(19) United States
(12) Patent Application Publication
(10) Pub. No.: US 2021/0230369 A1
(43) Pub. Date: Jul. 29, 2021

(54) POLYIMIDE, METHOD FOR PREPARING THE SAME, AND FLEXIBLE OLED PANEL

(71) Applicant: Wuhan China Star Optoelectronics Semiconductor Display Technology Co., Ltd., Wuhan (CN)

(72) Inventor: Yamin WANG, Wuhan (CN)

(73) Assignee: Wuhan China Star Optoelectronics Semiconductor Display Technology Co., Ltd., Wuhan (CN)

(21) Appl. No.: 16/625,716

(22) PCT Filed: Nov. 5, 2019
(86) PCT No.: PCT/CN2019/115765

§ 371 Date: Dec. 22, 2019

(30) Foreign Application Priority Data
Sep. 3, 2019 (CN) 201910827223.8

(51) Int. Cl. C08G 73/10; H01L 51/00

(52) U.S. Cl. CPC C08G 73/1085; C08G 73/1071; C08G 73/1039; H01L 27/32; H01L 51/0035; H01L 51/0097; C08G 73/1007

(57) ABSTRACT

A polyimide, a method for preparing the same, and a flexible organic light emitting diode (OLED) panel are provided. In the provided polyimide, a repeating unit of the polyimide includes an asymmetric structural group, and the asymmetric structural group includes a conjugated aromatic side group. The conjugated aromatic side group includes two or more benzene rings.

### FIELD OF INVENTION

The present disclosure relates to the field of organic light emitting diode (OLED) materials, and particularly relates to a polyimide, a method for preparing the same, and a flexible OLED panel.

### BACKGROUND OF INVENTION

Organic light emitting diode (OLED) display technology is the most active development direction of display panels in recent years, and has excellent characteristics of light weight, flexibility, foldability, and even crimpability. Among them, a flexible substrate, used as a support and protection component of the whole flexible device, not only has an important impact on the display quality of the device, but also directly affects the lifetime of the device. Polyimide (PI) is a kind of polymer material with repeating units of imide ring. The rigid imide ring gives the material excellent comprehensive properties, thereby making polyimide the preferred material for the flexible display substrates.

### SUMMARY OF INVENTION

### Technical Problems

Conventional polyimide materials often have dense rigid structures and strong intermolecular interactions, which ultimately lead to poor processing properties, dark color, etc., limiting the wide applications of polyimide. At present, methods for improving the processing properties of polyimide mainly focus on structural modification, such as introduction of long aliphatic chains, bulky fluorine side groups, introduction of asymmetric structures, to destroy regularity. However, in most cases, with the increase of light transmittance, thermal properties and mechanical properties always decreases.

### Technical Solutions

To solve the above problems, the present disclosure provides technical solutions as follows.

The present disclosure provides a polyimide. A repeating unit of the polyimide includes an asymmetric structural group, and the asymmetric structural group includes a conjugated aromatic side group including two or more benzene rings.

The polyimide according to an embodiment of the present disclosure, the asymmetric structural group is an asymmetric carbazolyl derivative.

The polyimide according to an embodiment of the present disclosure, a structure of the polyimide is represented by a formula (1):

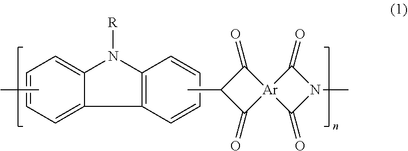

R is selected from

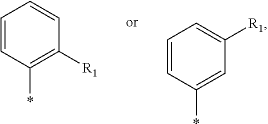

and R₁ is a C₆₋₃₀ aryl group, a C₃₋₃₀ heteroaryl group, a C₆₋₃₀ halogenated aryl group, or a C₆₋₃₀ arylamine group.

Ar is a C₆₋₃₀ aryl group, a C₁₂₋₃₀ aryl ketone group, or a C₁₂₋₃₀ aryl ether group.

The n is any integer from 1000 to 2500.

The polyimide according to an embodiment of the present disclosure, a structure of the R₁ is selected from any one of the following formulas:

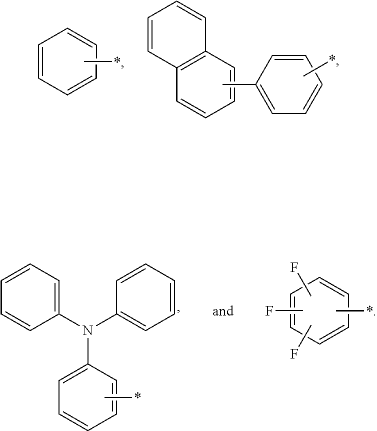

The polyimide according to an embodiment of the present disclosure, a structure of the Ar is selected from any one of the following formulas:

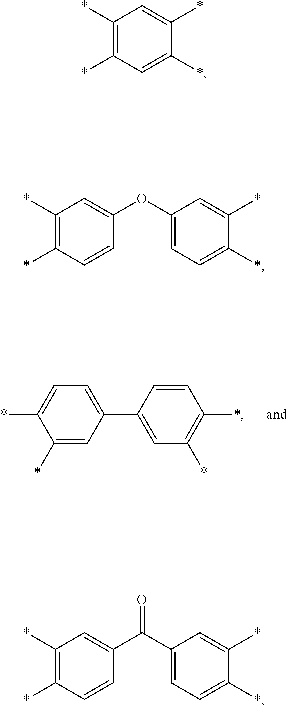

The polyimide according to an embodiment of the present disclosure, a structure of the polyimide is selected from any one of the following formulas:

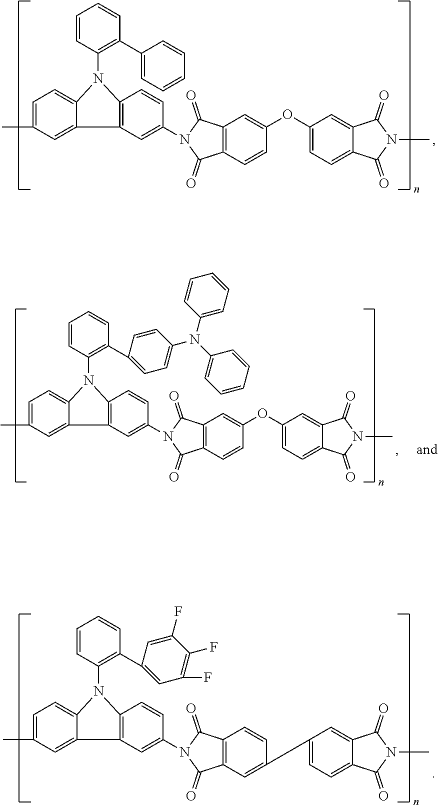

The present disclosure further provides a method for preparing a polyimide including the following steps.

A step S1, a diaminocarbazole derivative

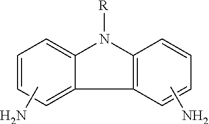

and a dianhydride monomer

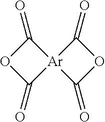

are dissolved in a first organic solvent under argon gas protection, and stirred and reacted for a first time at a first temperature to obtain a first reaction solution.

R is selected from

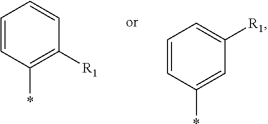

and R₁ is a C₆₋₃₀ aryl group, a C₃₋₃₀ heteroaryl group, a C₆₋₃₀ halogenated aryl group, or a C₆₋₃₀ arylamine group.

A step S2, the first reaction solution is taken and a second organic solvent is added thereto, a temperature is raised to a second temperature and reacted for a second time, and then the temperature is cooled to a third temperature under argon gas protection, so as to obtain a reaction solution. Filtration is performed on the obtained reaction solution using an organic filter membrane to obtain a filtrate.

A step S3, the filtrate is coated on a substrate, dried in a vacuum environment at a fourth temperature to remove 60 to 80 wt % of the first organic solvent and the second organic solvent, and then transferred into a high temperature furnace to heat at a fifth temperature, so as to obtain the substrate attached with a thin film.

A step S4, the substrate attached with the thin film is immersed in deionized water for a third time, and the thin film attached on the substrate is peeled off. Then, the thin film is dried at a sixth temperature to obtain a polyimide film.

The method for preparing the polyimide according to an embodiment of the present disclosure, in the step S1, a molar ratio of the diaminocarbazole derivative to the dianhydride monomer is 1:(0.67 to 1.5).

The method for preparing the polyimide according to an embodiment of the present disclosure, in the step S1, the first temperature is 10 to 60° C., and the first time is 24 to 96 hours.

The method for preparing the polyimide according to an embodiment of the present disclosure, in the step S2, the second temperature is 150 to 250° C., the second time is 4 to 6 hours, and the third temperature is 20 to 90° C.

The method for preparing the polyimide according to an embodiment of the present disclosure, in the step S3, the fourth temperature is 60 to 100° C., and the fourth temperature is 420 to 500° C.

The method for preparing the polyimide according to an embodiment of the present disclosure, in the step S4, the third time is 72 to 96 hours, and the sixth temperature is 60 to 80° C.

The method for preparing the polyimide according to an embodiment of the present disclosure, in the step S1, the first organic solvent is N-methylpyrrolidone.

The method for preparing the polyimide according to an embodiment of the present disclosure, in the step S1, a structure of R₁ is selected from any one of the following formulas:

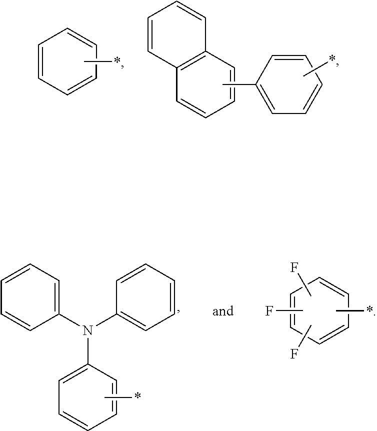

The method for preparing the polyimide according to an embodiment of the present disclosure, in the step S2, the second organic solvent is toluene.

The method for preparing the polyimide according to an embodiment of the present disclosure, a method for preparing the diaminocarbazole derivative

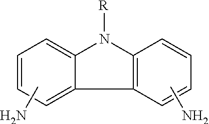

in the step S1 includes the following steps. Diaminocarbazole

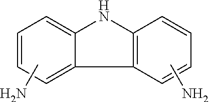

and an organotin catalyst are dissolved in anhydrous acetic acid, R—Br is added, stirred and reacted for 3 to 5 hours under argon gas protection, and a pH value is adjusted to 12 to 13 using a sodium hydroxide solution after finishing, so as to obtain a precipitated precipitation. The precipitated precipitation is washed, purified and then dried to obtain.

R is selected from

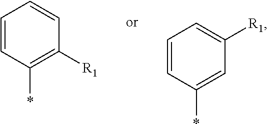

and R₁ is a C₆₋₃₀ aryl group, a C₃₋₃₀ heteroaryl group, a C₆₋₃₀ halogenated aryl group, or a C₆₋₃₀ arylamine group.

The method for preparing the polyimide according to an embodiment of the present disclosure, after removing 60 to 80 wt % of the first organic solvent and the second organic solvent, the step S3 further includes the following steps. The substrate is transferred into the high temperature furnace at a temperature of 100 to 140° C., stood for 20 to 60 mins. Then, raising a temperature to 180 to 380° C. at a heating rate of 1 to 10° C./min to heat for 10 to 60 mins is repeated once or more, then the temperature is raised to 420 to 500° C. at a heating rate of 1 to 10° C./min to heat for 20 to 90 mins, and finally the temperature is cooled to 180° C. or lower at a cooling rate of 1 to 10° C./min. Then, the substrate is taken out of the high temperature furnace.

The method for preparing the polyimide according to an embodiment of the present disclosure, after removing 60 to 80 wt % of the first organic solvent and the second organic solvent, the step S3 further includes the following steps. The substrate is transferred into the high temperature furnace at a temperature of 100 to 140° C., stood for 20 to 60 mins, a temperature is raised to 420 to 500° C. at a heating rate of 1 to 10° C./min to heat for 40 to 90 mins, and finally the temperature is cooled to 180° C. or lower at a cooling rate of 1 to 10° C./min. Then, the substrate is taken out of the high temperature furnace.

The present disclosure further provides a flexible OLED panel, and the flexible OLED panel includes the above polyimide.

### Beneficial Effects

The beneficial effect of the present disclosure is that the asymmetric structure and large conjugated aromatic side groups are introduced into the polyimide to obtain excellent properties. First, the introduction of such asymmetric structure reduces the regularity in the polymer chains, thereby effectively reducing the closely packing of the polymer chains and reducing chain interactions. Second, the benzene ring structure in the introduced aromatic side groups is conducive to improve the refractive index of the overall structure, thereby increasing the light transmittance of the polymer. Moreover, the asymmetric aromatic ring structure in the polymer can increase the content of the aromatic unit, thereby improving the thermal stability of the polymer. Therefore, the polyimide thin film having high transmittance, high stability, and desirable mechanical properties can be prepared, which can be used as an excellent OLED substrate material.

### DESCRIPTION OF DRAWINGS

In order to clearly illustrate the embodiments of the present disclosure, the following briefly introduces the accompanying drawings used in the embodiments. Obviously, the drawings in the following description merely show some of the embodiments of the present disclosure. As regards one of ordinary skill in the art, other drawings may be obtained in accordance with these accompanying drawings without making creative efforts.

FIG. 1 is a schematic view showing steps of high temperature heat of polyimide in a first embodiment of the present disclosure.

FIG. 2 is a schematic view showing steps of high temperature heat of polyimide in a second embodiment of the present disclosure.

FIG. 3 is a schematic view showing steps of high temperature heat of polyimide in a third embodiment of the present disclosure.

FIG. 4 is a fitting diagram of transmittance test data of the polyimide in the first embodiment of the present disclosure.

FIG. 5 is a fitting diagram of thermogravimetric test data of the polyimide in the first embodiment of the present disclosure.

### DETAILED DESCRIPTION OF PREFERRED EMBODIMENTS

The technical solutions in the embodiments of the present disclosure is clearly and completely described in the following with reference to the accompanying drawings in the embodiments of the present disclosure. It is obvious that the described embodiments are only a part of the embodiments of the present disclosure, and not all of the embodiments. Based on the embodiments of the present disclosure, all other embodiments obtained by those skilled in the art without creative effort are within the scope of protection of the present disclosure.

First embodiment: preparation of polyimide 1. The structural formula thereof is as follows:

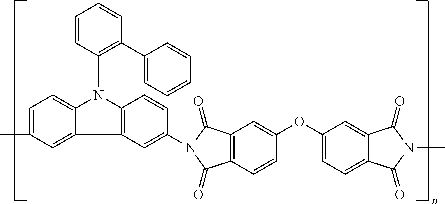

The synthesis pathway is as follows:

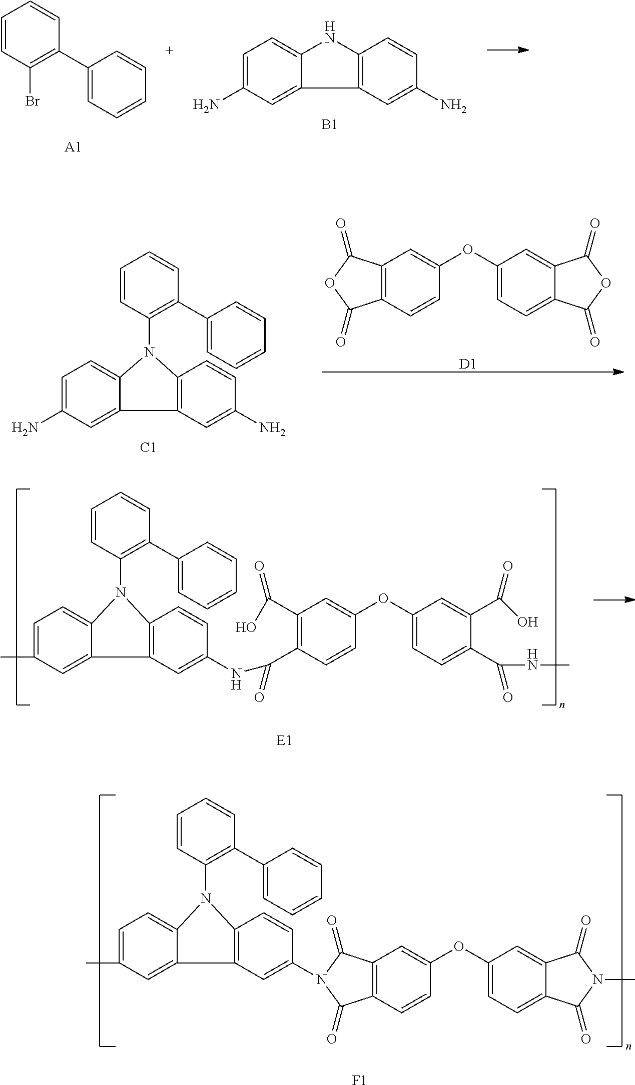

The synthesis steps are as follows:

1. Under argon gas protection, a compound A1 (10 mol) and dibutyltin dilaurate (6 mol) were added into a reaction device, and then anhydrous acetic acid was added to dissolve them. After a solid was dissolved and a solution was clarified, a compound B1 (11 mol) was slowly added. Then, the reaction was carried out under stirring at 200 rpm for 5 hours. After the reaction was finished, the solution was cooled to room temperature, and then a pH value was adjusted to 12 using a NaOH solution. A large amount of gray precipitate was precipitated, and washed with distilled water, and after suction filtration, a filter cake was stored and placed in a vacuum drying oven to dry at 60° C. for 8 hours. Tetrahydrofuran (THF) was added to the dried filter cake, stirred for 15 mins, and filtered to obtain a brown filtrate. The filtrate was evaporated to obtain a gray solid, then recrystallized using ethanol/water (volume ratio is 1:1) under argon gas protection, filtered, and washed twice using ethanol. The final obtained solid was placed in a vacuum drying oven to dry at 60° C. for 24 hours, so as to obtain a compound C1.

2. Under argon gas protection, the compound C1 (1 mol) was completely dissolved in a solvent (N-methylpyrrolidone, NMP), and then a compound D1 (1 mol) (dianhydride monomer) was added. A mixture was continuously stirred and reacted at room temperature for 24 hours, so as to obtain a polymer E1 solution.

3. Toluene (10 mL) was added to the obtained polymer E1 solution, and a mixture was heated to 150° C. in an argon atmosphere to react for 6 hours, and then cooled to 80° C. The obtained solution was filtered using an organic filter membrane, and the obtained filtrate was coated on a glass substrate, and then placed at a constant temperature of 80° C. under vacuum environment for 0.5 hours to remove 70% of NMP solvent.

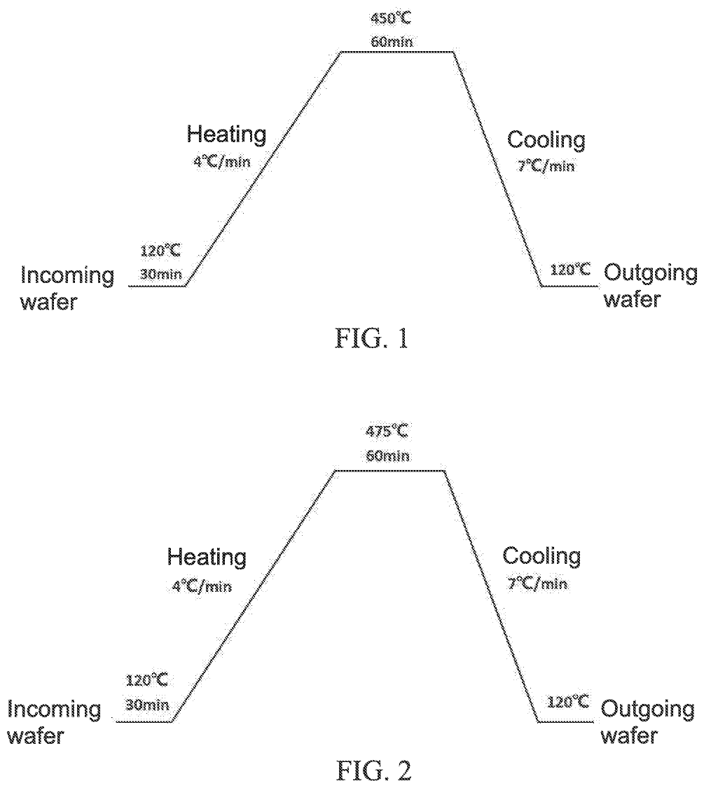

4. The glass substrate attached with a thin film was transferred into a high temperature furnace. The incoming wafer temperature was 120° C., and the glass substrate was stood at a constant temperature for 30 mins. Then, the temperature was heated to 450° C. at a heating rate of 4° C./min, and the glass substrate was heated at a constant temperature for 60 mins. Afterwards, the temperature was cooled to 120° C. at a cooling rate of 7° C./min, and the glass substrate was taken out of the high temperature furnace (referring to FIG. 1 in detail for the high temperature heating process). Then, the whole glass substrate and the film were immersed in deionized water for 72 hours. A polyimide thin film was peeled off, and dried at 80° C. Finally, a polyimide film was obtained.

The obtained polyimide thin film was subjected to a transmittance test. The test results are shown as FIG. 4, and the transmittance at a wavelength of 550 nm is close to 80%.

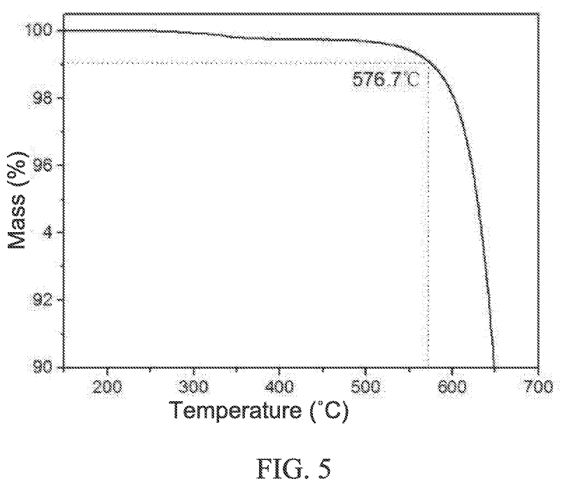

The obtained polyimide thin film was subjected to a thermogravimetric test. The test results are shown as FIG. 5, and the temperature at which the weight loss mass is 1% is 576.6° C.

Second embodiment: preparation of polyimide 2. The structural formula thereof is as follows:

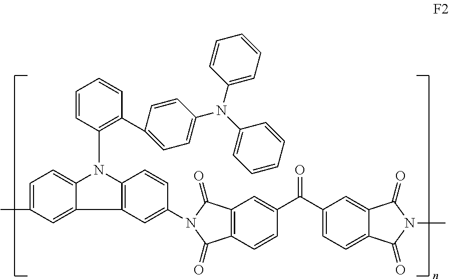

The synthesis pathway is as follows:

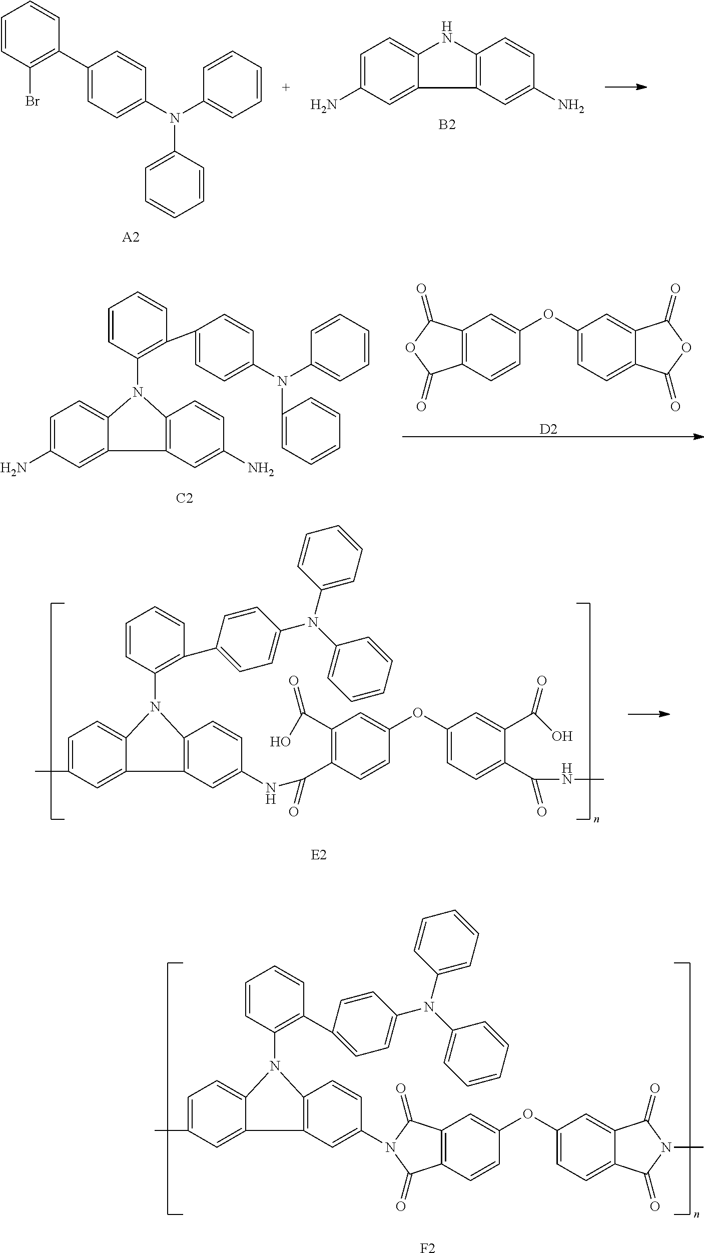

The synthesis steps are as follows:

1. Under argon gas protection, a compound A2 (10 mol) and dibutyltin dilaurate (5 mol) were added into a reaction device, and then anhydrous acetic acid was added to dissolve them. After a solid was dissolved and a solution was clarified, a compound B2 (15 mol) was slowly added. Then, the reaction was carried out under stirring at 400 rpm for 4 hours. After the reaction was finished, the solution was cooled to room temperature, and then a pH value was adjusted to 13 using a NaOH solution. A large amount of gray precipitate was precipitated, and washed with distilled water, and after suction filtration, a filter cake was stored and placed in a vacuum drying oven to dry at 60° C. for 10 hours. Tetrahydrofuran (THF) was added to the dried filter cake, stirred for 15 mins, and filtered to obtain a brown filtrate. The filtrate was evaporated to obtain a gray solid, then recrystallized using ethanol/water (volume ratio is 9:1) under argon gas protection, filtered, and washed twice using ethanol. The final obtained solid was placed in a vacuum drying oven to dry at 60° C. for 30 hours, so as to obtain a compound C2.

2. Under argon gas protection, the compound C1 (1 mol) was completely dissolved in a solvent (N-methylpyrrolidone, NMP), and then a compound D2 (1.5 mol) (dianhydride monomer) was added. A mixture was continuously stirred and reacted at room temperature for 48 hours, so as to obtain a polymer E2 solution.

3. Toluene (8 mL) was added to the obtained polymer E2 solution, and a mixture was heated to 200° C. in an argon atmosphere to react for 5 hours, and then cooled to 80° C. The obtained solution was filtered using an organic filter membrane, and the obtained filtrate was coated on a glass substrate, and then placed at a constant temperature of 80° C. under vacuum environment for 1 hour to remove 70% of NMP solvent.

4. The glass substrate attached with a thin film was transferred into a high temperature furnace. The incoming wafer temperature was 120° C., and the glass substrate was stood at a constant temperature for 30 mins. Then, the temperature was heated to 475° C. at a heating rate of 4° C./min, and the glass substrate was heated at a constant temperature for 60 mins. Afterwards, the temperature was cooled to 120° C. at a cooling rate of 7° C./min, and the glass substrate was taken out of the high temperature furnace (referring to FIG. 2 in detail for the high temperature heating process). Then, the whole glass substrate and the film were immersed in deionized water for 82 hours. A polyimide thin film was peeled off, and dried at 80° C. Finally, a polyimide film was obtained.

The obtained polyimide thin film was subjected to a thermogravimetric test, and the temperature at which the weight loss mass is 1% is 579.2° C.

The obtained polyimide thin film was subjected to a transmittance test, and the transmittance at a wavelength of 550 nm is close to 80%.

Third embodiment: preparation of polyimide 3. The structural formula thereof is as follows:

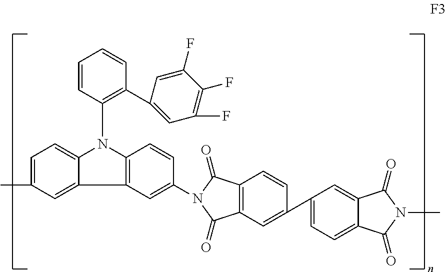

The synthesis pathway is as follows:

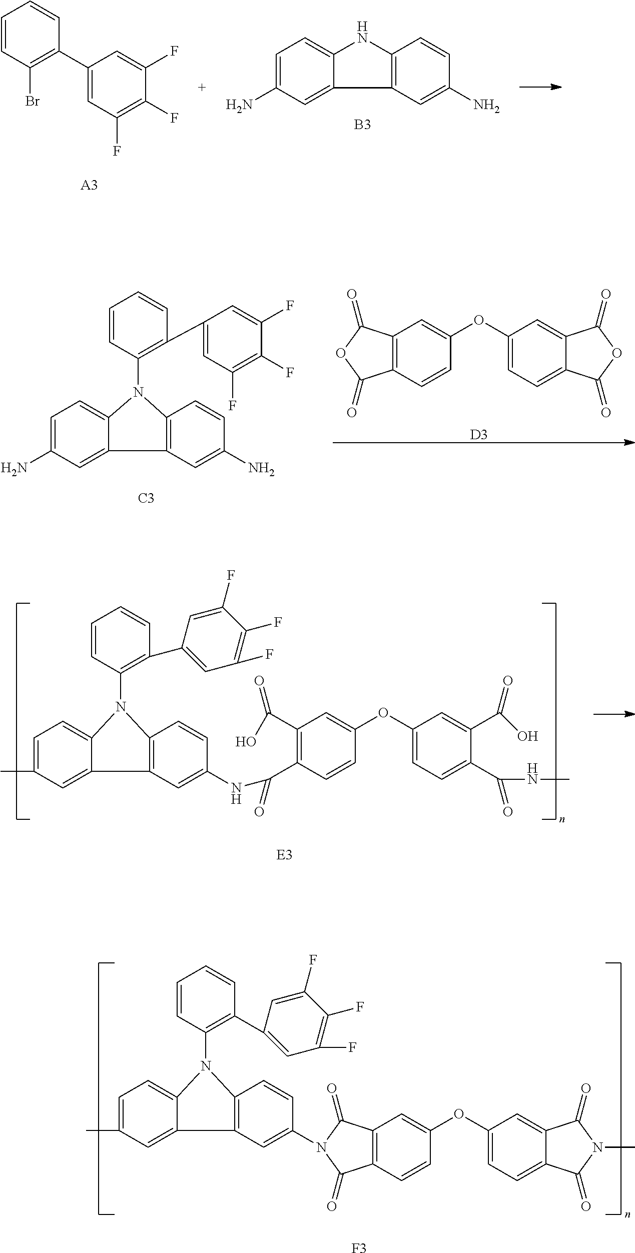

The synthesis steps are as follows:

1. Under argon gas protection, a compound A3 (15 mol) and dibutyltin dilaurate (7 mol) were added into a reaction device, and then anhydrous acetic acid was added to dissolve them. After a solid was dissolved and a solution was clarified, a compound B3 (10 mol) was slowly added. Then, the reaction was carried out under stirring at 500 rpm for 3 hours. After the reaction was finished, the solution was cooled to room temperature, and then a pH value was adjusted to 12.5 using a NaOH solution. A large amount of gray precipitate was precipitated, and washed with distilled water, and after suction filtration, a filter cake was stored and placed in a vacuum drying oven to dry at 60° C. for 9 hours. Tetrahydrofuran (THF) was added to the dried filter cake, stirred for 15 mins, and filtered to obtain a brown filtrate. The filtrate was evaporated to obtain a gray solid, then recrystallized using ethanol/water (volume ratio is 1:9) under argon gas protection, filtered, and washed twice using ethanol. The final obtained solid was placed in a vacuum drying oven to dry at 60° C. for 48 hours, so as to obtain a compound C3.

2. Under argon gas protection, the compound C3 (1.5 mol) was completely dissolved in a solvent (N-methylpyrrolidone, NMP), and then a compound D3 (1 mol) (dianhydride monomer) was added. A mixture was continuously stirred and reacted at room temperature for 96 hours, so as to obtain a polymer E3 solution.

3. Toluene (7 mL) was added to the obtained polymer E2 solution, and a mixture was heated to 250° C. in an argon atmosphere to react for 4 hours, and then cooled to 80° C. The obtained solution was filtered using an organic filter membrane, and the obtained filtrate was coated on a glass substrate, and then placed at a constant temperature of 80° C. under vacuum environment for 1 hour to remove 70% of NMP solvent.

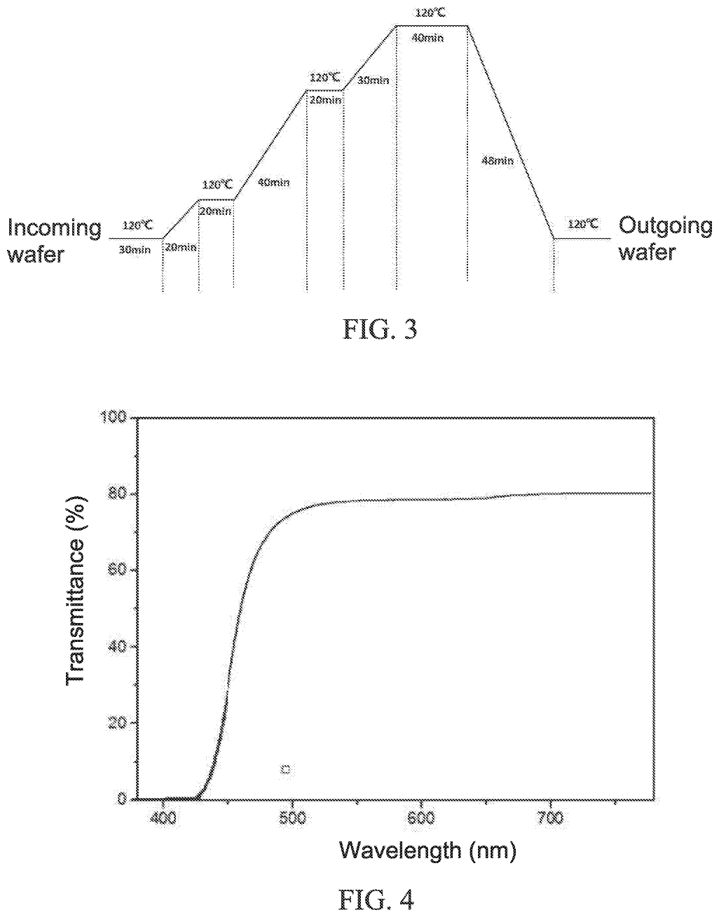

4. The glass substrate attached with a thin film was transferred into a high temperature furnace. The incoming wafer temperature was 120° C., and the glass substrate was stood at a constant temperature for 30 mins. Then, the temperature was heated to 180° C. at a constant temperature at a heating time of 20 mins, and the glass substrate was stood for 20 mins. Afterwards, the temperature was heated to 350° C. at a constant temperature at a heating time of 40 mins, and the glass substrate was stood for 20 mins. Thereafter, the temperature was heated to 450° C. at a constant temperature at a heating time of 30 mins, and the glass substrate was heated for 40 mins. Finally, the temperature was cooled to 120° C. at a constant temperature at a cooling time of 48 mins, and the glass substrate was taken out of the high temperature furnace (referring to FIG. 3 in detail for the high temperature heating process).

Then, the whole glass substrate and the film were immersed in deionized water for 96 hours. A polyimide thin film was peeled off, and dried at 80° C. Finally, a polyimide film was obtained.

The obtained polyimide thin film was subjected to a thermogravimetric test, and the temperature at which the weight loss mass is 1% is 573.9° C.

The obtained polyimide thin film was subjected to a transmittance test, and the transmittance at a wavelength of 550 nm is close to 80%.

It can be determined from the above embodiments that the polyimide of the present disclosure has high transmittance and thermal stability and is suitable for application in the field of flexible organic light emitting diode (OLED) panels.

The polyimide and the method for preparing the same provided by the embodiments of the disclosure are described in detail as above. The principle and embodiments of the disclosure have been set forth by way of specific examples, and the descriptions of the embodiments are merely used for understanding the inventive method and the core idea thereof. Those skilled in the art can make changes to the embodiments and their application scopes in light of the spirit of the disclosure. Accordingly, the descriptions shall not be taken as limiting the disclosure.

What is claimed is:

1. A polyimide, wherein a repeating unit of the polyimide comprises an asymmetric structural group, and the asymmetric structural group comprises a conjugated aromatic side group including two or more benzene rings.

2. The polyimide according to claim 1, wherein the asymmetric structural group is an asymmetric carbazolyl derivative.

3. The polyimide according to claim 1, wherein a structure of the polyimide is represented by a formula (1): 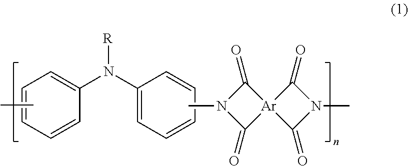
wherein R is selected from 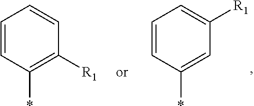
R₁ is a C₆₋₃₀ aryl group, a C₃₋₃₀ heteroaryl group, a C₆₋₃₀ halogenated aryl group, or a C₆₋₃₀ arylamine group;
Ar is a C₆₋₃₀ aryl group, a C₁₂₋₃₀ aryl ketone group, or a C₁₂₋₃₀ aryl ether group; and
the n is any integer from 1000 to 2500.

4. The polyimide according to claim 3, wherein the R₁ is selected from any one of the following structural formulas:

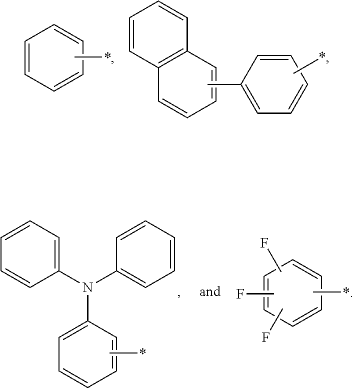

5. The polyimide according to claim 3, wherein the Ar is selected from any one of the following structural formulas:

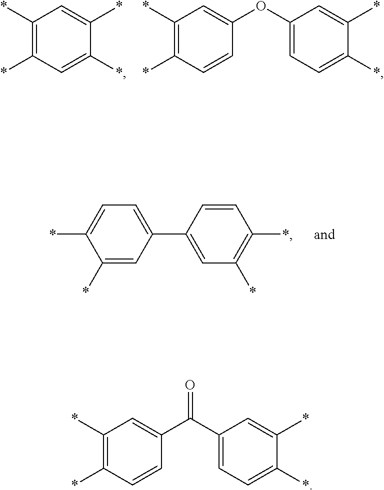

6. The polyimide according to claim 3, wherein the polyimide is selected from any one of the following structural formulas:

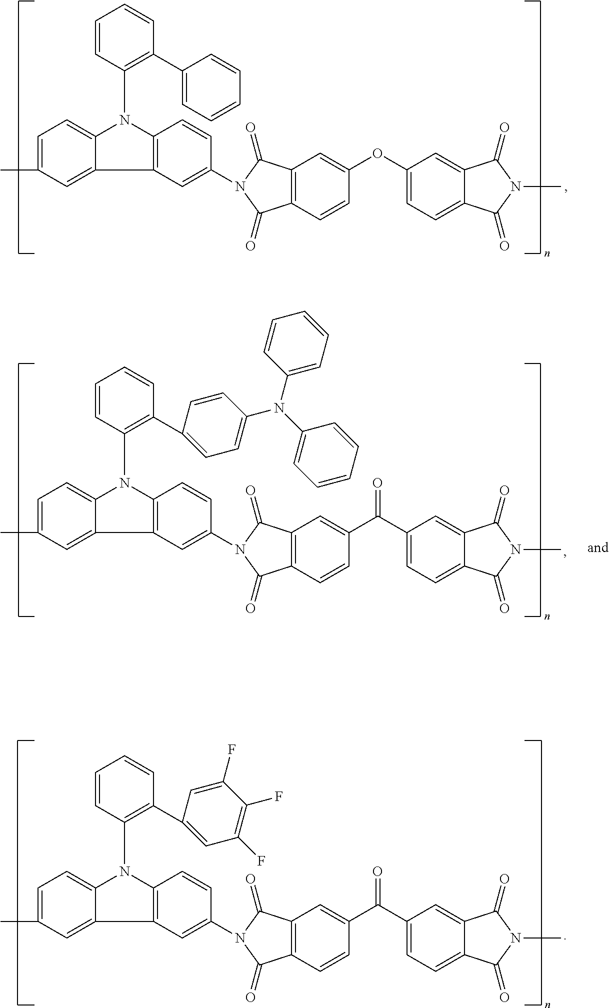

7. A method for preparing a polyimide, comprising:
a step S1 of dissolving a diaminocarbazole derivative 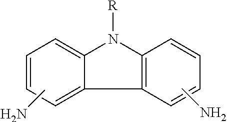
and a dianhydride monomer 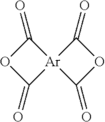
in a first organic solvent under argon gas protection, and stirring and reacting for a first time at a first temperature to obtain a first reaction solution,
wherein R is selected from 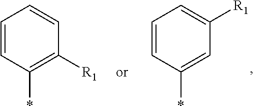
and R₁ is a C₆₋₃₀ aryl group, a C₃₋₃₀ heteroaryl group, a C₆₋₃₀ halogenated aryl group, or a C₆₋₃₀ arylamine group;
a step S2 of taking the first reaction solution and adding a second organic solvent thereto, raising to a second temperature and reacting for a second time and then cooling to a third temperature under argon gas protection so as to obtain a reaction solution, and performing filtration on the obtained reaction solution using an organic filter membrane to obtain a filtrate;
a step S3 of coating the filtrate on a substrate, drying in a vacuum environment at a fourth temperature to remove 60 to 80 wt % of the first organic solvent and the second organic solvent, and then transferring into a high temperature furnace to heat at a fifth temperature, so as to obtain the substrate attached with a thin film; and
a step S4 of immersing the substrate attached with the thin film in deionized water for a third time, peeling off the thin film attached on the substrate, and then drying the thin film at a sixth temperature to obtain a polyimide film.

8. The method for preparing the polyimide according to claim 7, wherein in the step S1, a molar ratio of the diaminocarbazole derivative to the dianhydride monomer is 1:(0.67 to 1.5).

9. The method for preparing the polyimide according to claim 7, wherein in the step S1, the first temperature is 10 to 60° C., and the first time is 24 to 96 hours.

10. The method for preparing the polyimide according to claim 7, wherein in the step S2, the second temperature is 150 to 250° C., the second time is 4 to 6 hours, and the third temperature is 20 to 90° C.

11. The method for preparing the polyimide according to claim 7, wherein in the step S3, the fourth temperature is 60 to 100° C., and the fourth temperature is 420 to 500° C.

12. The method for preparing the polyimide according to claim 7, wherein in the step S4, the third time is 72 to 96 hours, and the sixth temperature is 60 to 80° C.

13. The method for preparing the polyimide according to claim 7, wherein in the step S1, the first organic solvent is N-methylpyrrolidone.

14. The method for preparing the polyimide according to claim 7, wherein in the step S1, the R₁ is selected from any one of the following structural formulas:

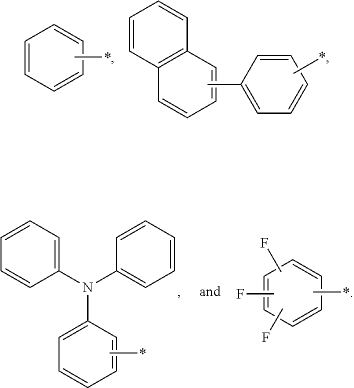

15. The method for preparing the polyimide according to claim 7, wherein in the step S2, the second organic solvent is toluene.

16. The method for preparing the polyimide according to claim 7, wherein a method for preparing the diaminocarbazole derivative 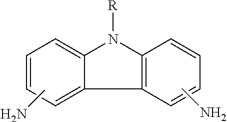
in the step S1 comprises: dissolving diaminocarbazole 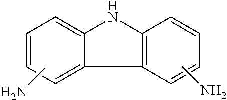
and an organotin catalyst in anhydrous acetic acid, adding R—Br, stirring and reacting for 3 to 5 hours under argon gas protection, adjusting a pH value to 12 to 13 using a sodium hydroxide solution after finishing, so as to obtain a precipitated precipitation, washing the precipitated precipitation, and purifying and then drying to obtain;
wherein the R is selected from 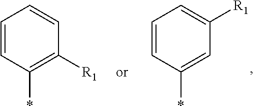
and the R₁ is a C₆₋₃₀ aryl group, a C₃₋₃₀ heteroaryl group, a C₆₋₃₀ halogenated aryl group, or a C₆₋₃₀ arylamine group.

17. The method for preparing the polyimide according to claim 7, wherein after removing 60 to 80 wt % of the first organic solvent and the second organic solvent, the step S3 further comprises:
transferring the substrate into the high temperature furnace at a temperature of 100 to 140° C.;
standing for 20 to 60 mins;
repeating once or more of raising to 180 to 380° C. at a heating rate of 1 to 10° C./min to heat for 10 to 60 mins, then raising to 420 to 500° C. at a heating rate of 1 to 10° C./min to heat for 20 to 90 mins, and finally cooling to 180° C. or lower at a cooling rate of 1 to 10° C./min; and
then taking the substrate out of the high temperature furnace.

18. The method for preparing the polyimide according to claim 7, wherein after removing 60 to 80 wt % of the first organic solvent and the second organic solvent, the step S3 further comprises:
transferring the substrate into the high temperature furnace at a temperature of 100 to 140° C.;
standing for 20 to 60 mins;
raising to 420 to 500° C. at a heating rate of 1 to 10° C./min to heat for 40 to 90 mins, and finally cooling to 180° C. or lower at a cooling rate of 1 to 10° C./min; and
then taking the substrate out of the high temperature furnace.

19. A flexible organic light emitting diode (OLED) panel, wherein the flexible OLED panel comprises the polyimide according to claim 1.
